(19) United States
(12) Patent Application Publication
(10) Pub. No.: US 2005/0035767 A1
(43) Pub. Date: Feb. 17, 2005

(54) Plug detector for an electrical test instrument

(76) Inventor: William Dean Hardy, Deal (GB)

Correspondence Address: George T. Noe;Fluke Corporation, P.O. Box 9090, Everett, WA, 98206-9090, US

(21) Appl. No.: 10/639,039

(22) Filed: Aug. 11, 2003

(51) Int. Cl. G01R 31/08; H01H 31/04

(52) U.S. Cl. 324/538

(57) ABSTRACT

A plug detector for an electronic test instrument includes an isolation transformer interposed between a jack socket and a plug detection circuit. The jack socket includes a split jack arrangement in which two halves of a jack socket are connected to opposite ends of a primary winding of the isolation transformer. When the primary winding is loaded due to the insertion of a jack plug, the primary winding is shorted and the impedance of a secondary winding changes. The detection circuit detects the change in impedance in the secondary winding and generates a detection signal to indicate plug detection.

### BACKGROUND OF THE INVENTION

This invention relates generally to electrical test instruments, and in particular to detecting whether test leads are plugged into such instruments.

Sophisticated electronic test instruments for testing electrical circuits are capable of performing multiple functions, including not only measuring several ranges of ac and dc voltages, but sourcing current and voltage in order to measure resistance and perform other testing of electrical circuits or multiple-phase power systems. It is common to provide different test leads with different types of connectors to an attempt to ensure that test leads and inputs to the test instrument are properly matched up for a particular test. However, operator mistakes still can happen, and a wrong test lead plugged into a wrong jack can range from incorrect measurement results to catastrophic failure of the instrument caused by an arc blast, and perhaps even to injury or death.

It is desirable for an electronic test instrument to monitor the connection of test leads to its input terminals so that measurements can proceed only if test leads are connected correctly. As can be readily discerned, the advantages of such an arrangement include not only validity of measurements, but user safety as well.

One conventional method of detecting whether or not a test lead is properly connected is to use a detector circuit in conjunction with a split jack receptacle, the two halves of which are electrically connected together when a plug is inserted into the jack socket. The detection circuit usually includes an impedance path to ground through a voltage divider. A detection circuit of this type is disclosed in U.S. Pat. No. 6,281,673 to Zoellick et al. While this type of detector works well for low voltages, it does not work well for high voltages. That is, it is desired to isolate a connector plug from a detection circuit and other internal circuitry when high voltages are present on the plug.

### SUMMARY OF THE INVENTION

In accordance with the present invention, a plug detector for an electronic test instrument includes an isolation transformer interposed between a jack socket and a plug detection circuit. The jack socket includes a split jack arrangement in which two halves of a jack socket are electrically connected together when a jack plug is inserted into the socket, and are otherwise electrically isolated from each other. The two halves of the jack socket are connected to opposite ends of a primary winding of the isolation transformer. When the primary winding is loaded due to the insertion of a jack plug, the primary winding is shorted and the impedance of a secondary winding changes. The detection circuit detects the change in impedance in the secondary winding and generates a detection signal to indicate plug detection. Major benefits of this arrangement include not only relatively simple plug detection, but complete isolation via the transformer of the plug detector circuit from any voltages that may be present on the plug.

Other objects, features, and advantages of the present invention will become obvious to those having ordinary skill in the art upon a reading of the following description when taken in conjunction with the accompanying drawings.

### BRIEF DESCRIPTION OF THE DRAWINGS

FIG. 1 is a schematic diagram of an exemplary electronic test instrument for testing electrical circuits which includes plug detector circuits of the present invention;

FIG. 2 is a plug detector in accordance with the present invention; and

FIG. 3 is an exemplary plug detector circuit in accordance with the present invention.

### DETAILED DESCRIPTION OF THE INVENTION

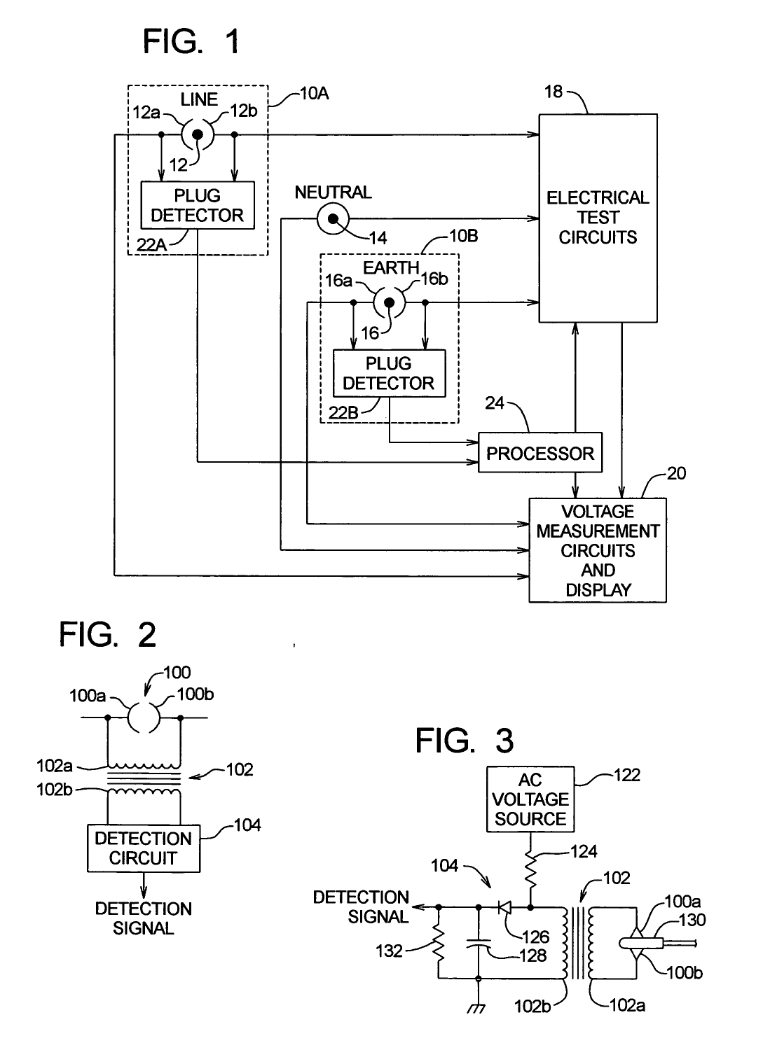

Referring to FIG. 1 of the drawings, there is shown a schematic representation of an exemplary electronic test instrument for testing electrical circuits, the test instrument including plug detector circuits 10A and 10B. The test instrument includes a LINE input jack socket 12, a NEUTRAL input jack socket 14, and an EARTH input jack socket 16. Input jack sockets 12, 14, and 16 are connected to provide inputs respectively to electrical test circuits 18 and voltage measurement circuits and display 20.

While the details of electrical test circuits 18 are not shown, such circuits are well known to those having ordinary skill in the art and typically include circuits for testing electrical circuits having residual current devices (RCDs) and measuring so-called loop currents and voltages (e.g., line-neutral and line-earth loops) found in three-phase power systems. Likewise, the details of the voltage measurements and display circuits 20 are not shown and are well known to those skilled in the digital multimeter art.

Sockets 12, 14, and 16 may suitably be industry-standard 4 millimeter sockets for receiving so-called banana plugs, which are commonly used with test leads. Note in FIG. 1 that the LINE input socket 12 and EARTH input socket 16 are modified to have split sockets, while NEUTRAL input socket 14 is not split. The two halves of sockets 12 and 16, which are labeled 12a-12b and 16a-16b, are connected to identical plug detectors 22A and 22B. The outputs of plug detectors 22A and 22B are applied as logic signals to a processor 24, which controls operation of the test instrument.

In operation, plug detector circuits 10A and 10B detect the presence (as well as the absence) of plugs plugged into the LINE and EARTH sockets 12 and 16, respectively. This allows the processor 24 to monitor the connection of test leads to the measurement terminals and permit tests or measurements to proceed only if the correct test leads are plugged in.

The plug detector circuits 10A and 10B are shown in more detail in FIG. 2. Since the plug detector circuits 10A and 10B are identical, the description of the circuit in FIG. 2 is applicable to both. The two halves 100a and 100b of a split socket 100 are connected to opposite ends of a primary winding 102a of a transformer 102. A secondary winding 102b of transformer 102 is connected to a detector circuit 104. When the primary winding 102a is loaded due to the insertion of a jack plug into split socket 100, the primary winding 102a is shorted and the impedance or inductive reactance of the secondary winding 102b changes. The detection circuit 104 detects the change in impedance in the secondary winding and generates a detection signal to indicate plug detection.

There are many methods known to those skilled in the art for measuring impedance and in particular detecting changes in the impedance of a transformer winding, and therefore detector circuit 104 may implemented in many forms. For example, in its most simple form, a voltage divider formed by the secondary winding in series with a resistor between an ac voltage source and ground will produce a detection signal when the transformer winding is shorted. It can readily be appreciated that more sophisticated forms of plug detection may implemented using transistors switches or flip-flops to generate detection signals when the primary winding is shorted. To provide a complete understanding of the present invention, however, an exemplary detection circuit proposed for a commercial embodiment is shown in FIG. 3.

Referring the exemplary detector circuit 104 shown in FIG. 3, a source of ac voltage 122, which may suitably be a clock or an oscillator, is connected through a current-limiting resistor 124 to one end of secondary winding 102b, the other end of which is connected to ground. Considering for the moment that no test lead is plugged into split socket 100, a diode 126 rectifies the clock voltage and charges a capacitor 128. The voltage developed across capacitor 128 is output as a logical one to processor 24.

In the proposed commercial embodiment, clock 122 is derived from the processor 24 and operates at a frequency of one megahertz. This frequency is not critical; however, it is important that the frequency be higher than the anticipated measurement frequency so that any signal reflected into the primary winding 102A of transformer 102 will have a negligible effect on measurements being made by the instrument.

For purposes of explanation, a plug 130, which may be a convention plug of the type known as a banana plug attached to one end of a test lead, is shown plugged into socket 100, electrically connecting the two halves 100a and 100b together. This of course short circuits the inductance of the transformer, causing capacitor 128 to discharge through a resistor 132. The reduced voltage across capacitor 128, then, is seen by processor 24 as a logical zero.

Accordingly, it can be discerned that when a plug 130 is plugged into split socket 100, it is detected by processor 24. Transformer 102 serves to isolate the detector circuitry on the secondary winding 102b from any measurement voltages present on plug 130. In the aforementioned proposed commercial embodiment of the present invention, transformer 102 is wound on a ferrite ring core with sufficient separation of windings to provide the required isolation.

While I have shown and described the preferred embodiment of my invention, it will be apparent to those skilled in the art that many changes and modifications may be made without departing from my invention in its broader aspects. It is therefore contemplated that the appended claims will cover all such changes and modifications as fall within the true scope of the invention.

1. A detector for detecting the presence of a plug in a split socket having first and second contacts that are electrically isolated from each other, comprising:
a transformer having a primary winding having opposite ends coupled respectively to said first and second contacts;
a detector circuit coupled to a secondary winding of said transformer for detecting changes in impedance of said secondary winding when said primary winding is shorted by a plug electrically connecting said first and second contacts together.

2. A plug detector, comprising:
an electrical socket for receiving said plug, said electrical socket being split into a first half and a second half;
a transformer having a primary winding and secondary winding, said primary winding having a first end connected to said first half of said electrical socket and a second end connected to said second half of said electrical socket; and
a detector circuit coupled to said secondary winding for detecting changes in impedance in said secondary winding, said detector circuit being electrically isolated from said electrical socket.
